(19) United States
(12) Patent Application Publication
(10) Pub. No.: US 2004/0053449 A1
(43) Pub. Date: Mar. 18, 2004

(54) Method for producing plastic active panel displays

(76) Inventors: Chich-Shang Chang, Taoyuan (TW); Wen-Tung Wang, Hsinchu (TW); Chiung-Wei Lin, Taipei (TW); Chi-Lin Chen, Hsinchu (TW)

Correspondence Address: BIRCH STEWART KOLASCH & BIRCH, PO BOX 747, FALLS CHURCH, VA, 22040-0747, US

(21) Appl. No.: 10/301,670

(22) Filed: Nov. 22, 2002

(30) Foreign Application Priority Data
Sep. 13, 2002 (TW) 91120976

(51) Int. Cl. H01L 21/00; H01L 21/84

(52) U.S. Cl. 438/149

(57) ABSTRACT

A method for producing plastic active panel displays. The method comprises: providing a glass substrate, followed by the formation of a sacrificial layer on top of the glass substrate, forming thin film transistor (TFT) on the sacrificial layer, forming a display material on the TFT, subjecting the glass substrate to laser so that the glass substrate and the sacrificial layer are detached from the TFT, thereby exposing the TFT, and attaching a plastic substrate to the TFT.

### BACKGROUND OF THE INVENTION

1. Field of the Invention

The present invention relates to a method for producing a panel display. In particular, the invention involves the production of plastic active panel displays.

2. Description of the Prior Art

In the further advancement of larger-area panel displays, lightness and thinness and deflectability are sought-after properties. Plastic material, light, soft, deflectable, and able to be made as thin as 0.1 mm, is the focus of recent study. However, the glass transition temperature of plastic material is about 180° C., which is low, when compared to the process temperature 300° C. for TFT (thin film transistor) and 400° C. for LTPS-TFT (low temperature polysilicon). Consequently, plastic material is inappropriate for TFT process. If an active panel display is produced directly on a plastic substrate, process temperature must be lowered to compensate for the plastic substrate. By doing so, characteristics of the TFT element cannot be maintained. In addition, production of TFT directly on a plastic substrate causes problems such as stress and static electricity, and the thermal expansion coefficient is high, a big problem for alighment during the lithography process. Therefore, it is very difficult to produce active panel diaplays on deflectable plastic substrates.

### SUMMARY OF THE INVENTION

In order to overcome the above problems, an object of the invention is to provide a method for producing plastic active panel displays, wherein major steps are the formation of thin film transistor (TFT) onto a glass substrate, followed by the formation of display material on the TFT, and lamination of a plastic substrate onto the display material. Next, the display is turned over to detach the glass substrate by laser ableation. Another plastic substrate is then laminated onto the TFT to form an plastic active panel display having plastic substrates on both sides.

In order to achieve the above objects, there is provided a method for producing plastic active panel displays, comprising: (a) providing a glass substrate, followed by the formation of a sacrificial layer on top of the glass substrate; (b) forming thin film transistor (TFT) on the sacrificial layer; (c) forming a display material on the TFT; (d) laminating a plastic substrate onto the display material; (e) subjecting the glass substrate to laser so that the glass substrate and the sacrificial layer are detached from the TFT, thereby exposing the TFT; and (f) attaching a plastic substrate to the TFT.

A preferable sacrificial layer in the present invention is amorphous silicon having a high concentration of hydrogen (H), with thickness of the sacrificial layer preferably 200˜10000 Å. The sacrificial layer, having a concentration of hydrogen is formed for laser ableation at a later step to detach the glass substrate from the sacrificial layer and TFT by hydro-cracking. The concentration of hydrogen must be sufficient to cause hydro-cracking, and the preferable range is 1˜40 vol %. Prefered energy of the laser is 20˜450 mJ/cm², such as XeCl, having wavelength of 308 nm.

In step (d), the lamination of the plastic substrate to the display material preferably uses highly transparent gel, such as UV gel, hot thermal gel, epoxy gel or other gel with high transparency. In addition, after the formation of the sacrificial layer in step (a), a protective layer is formed on the sacrificial layer so that the loss of hydrogen during the process is avoided. By doing so, a sufficient concentration of hydrogen for hydro-cracking at a later step of laser ableation is maintained. The protective layer is preferably SiN, SiO₂, TiO₂, or Al₂O₃. Thickness is preferably 500˜5000 Å.

After step (e), there is possible remaining sacrificial layer on the TFT, so an alkali solution can be used to remove it. Preferable alkali solution is tetramethyl ammoniumhydroxide or potassium hydroxide (KOH).

According to the method for producing plastic active panel displays of the present invention, there is no need to lower the process temperature, and good characteristics of displays are maintained. Moreover, TFT is formed on a glass substrate, not directly on a plastic substrate, thus preventing from problems such as stress, static electricity and alignment problems in lithography process due to high thermal expansion coefficient.

The present invention will become more fully understood from the detailed description given hereinbelow and the accompanying drawings, given by way of illustration only and thus not intended to be limitative of the present invention.

### BRIEF DESCRIPTION OF THE DRAWINGS

FIG. 1A˜1E illustrate cross-sections of the process for producing an plastic active panel display according to the embodiment of the present invention.

FIG. 2 illustrates the cross-section of a conventional thin film transistor (TFT).

### DETAILED DESCRIPTION OF THE INVENTION

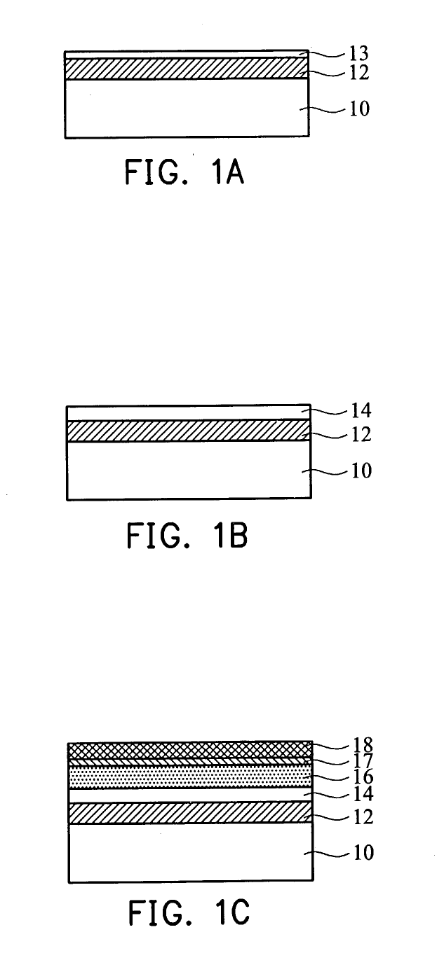

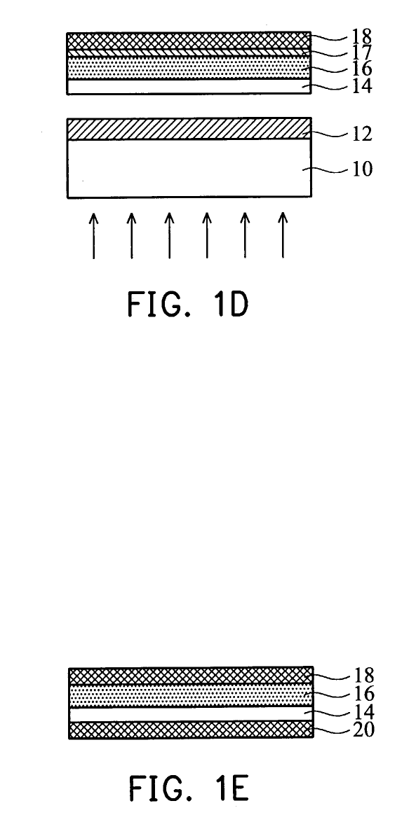

FIG. 1A˜1E illustrate cross-sections of the process for producing a plastic active panel display according to the present invention.

First, a sacrificial layer 12 is formed on a glass substrate 10, as shown in FIG. 1A. The sacrificial layer is preferably amorphous silicon with a preferable thickness of 200˜10000 Å. Formation of the sacrificial layer is carried out by chemical vapor deposition, such as plasma enhanced CVD or low pressure CVD. The sacrificial layer must contain a satisfactory concentration of hydrogen, preferably at 1˜40 vol % to cause hydro-cracking later in the laser ableation.

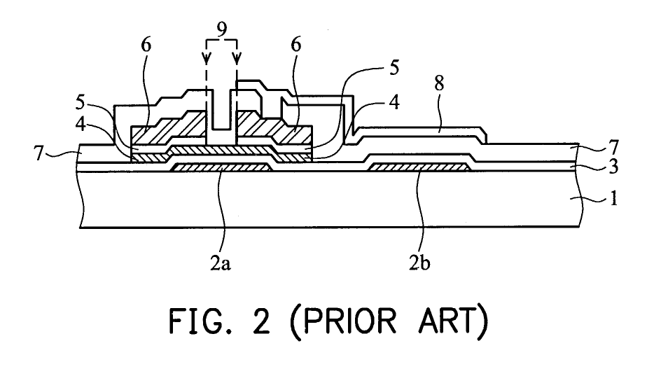

Next, a thin film transistor 14 is formed on the sacrificial layer, as shown in FIG. 1B. Layout of the TFT is not limited, all conventional TFTs are applicable. An example of TFT is shown in FIGS. 2. In FIG. 2, 1 denotes substrate, such as glass or quartz, 2a represents conductive layer, as the gate of TFT. 2b is the electrode of the storage capacitor, 3 is the gate insulation layer, and 4 is the semiconductor layer of the TFT, of amorphous silicon. 5 is silicon doped with N+ dopant, and is used as source/drain of TFT. 6 is the electrode layer, usually metal. 7 denotes a passivation layer and 8 is the transparent conductive layer, usually indium tin oxide (ITO), the lower electrode driving the liquid crystal. 9 denotes the channel region.

Before forming TFT, a protective layer 13 is optionally formed on the sacrificial layer 12, as shown in FIG. 1A. The protective layer 13 is preferably SiN, SiO₂, TiO₂ or Al₂O₃. Preferable thickness is 500˜5000 Å. The protective layer is used to minimize the loss of hydrogen during the process and maintain a satisfactory concentration of hydrogen. By doing so, it is ensured that hydro-cracking at later stage is induced.

Then, as shown in FIG. 1C, display material 16 is formed on the TFT 14. The display material is liquid crystal, organic light emitting diode, polymer light emitting diode or electrophoresis display material. Next, a plastic substrate 18 is laminated onto the display material 16 by highly transparent gel 17, which is preferably UV gel, thermal melt gel, epoxy gel, or other gel with high transparency. In FIG. 1C, a display with plastic substrate on the top and a glass substrate at the bottom is illustrated.

Excimer laser is then used, in FIG. 1D, to cause hydro-cracking of the sacrificial layer 12. In this embodiment XeCl having wavelength of 308 nm is used. During the laser process, hydrogen in the sacrificial layer 12 is given energy to cause hydro-cracking, thereby detaching the sacrificial layer 12 from the TFT 14. Preferable laser energy range is 20˜450 mJ/cm². Next, a plastic substrate 20 is laminated onto the TFT 14 by the same method described above, using highly transparent gel, to form a plastic active panel display having plastic substrates both on top and bottom, as shown in FIG. 1E.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method for producing plastic active panel displays, comprising:
providing a glass substrate, followed by the formation of a sacrificial layer on top of the glass substrate;
forming thin film transistor (TFT) on the sacrificial layer;
forming a display material on the TFT;
laminating a plastic substrate on the display material;
subjecting the glass substrate to laser so that the glass substrate and the sacrificial layer are detached from the TFT, thereby exposing the TFT; and
attaching a plastic substrate to the TFT.

2. The method as claimed in claim 1, wherein the sacrifical layer is amorphous Si.

3. The method as claimed in claim 2, wherein the sacrificial layer comprises 1˜40 vol % of hydrogen.

4. The method as claimed in claim 1, wherein the thickness of the sacrificial layer is 200˜10000 Å.

5. The method as claimed in claim 1, wherein the step (e) utilizes excimer laser.

6. The method as claimed in claim 5, wherein XeCl is used in the excimer laser.

7. The method as claimed in claim 5, wherein the energy of the excimer laser is 20˜450 mJ/cm².

8. The method claimed in claim 1, wherein the plastic sustrates are laminated onto the display material by highly transparent gel.

9. The method as claimed in claim 8, wherein the highly transparent gel is UV gel, hot thermal gel, or epoxy gel.

10. The method as claimed in claim 1, wherein providing the substrate further comprises forming a protective layer on the sacrificial layer.

11. The method as claimed in claim 10, wherein the protective layer is SiN, SiO₂, TiO₂ or Al₂O₃.

12. The method as claimed in claim 11, wherein the thickness of the protective layer is 500˜5000 Å.

13. The method as claimed in claim 1, wherein subjecting the substrate to laser further comprises removing sacrificial layer by alkali solution.

14. The method as claimed in claim 13, wherein the alkali solution is tetramethyl ammonium hydroxide, or KOH.

15. The method as claimed in claim 1, wherein the process temperature of forming the TFT is 300˜450 degrees.

16. The method as claimed in claim 1, wherein the display material is liquid crystal, organic light emitting diode, polymer light emitting diode or electrophoresis display material.
